(19) United States
(12) Patent Application Publication
(10) Pub. No.: US 2016/0197103 A1
(43) Pub. Date: Jul. 7, 2016

(54) THIN-FILM TRANSISTOR SUBSTRATE

(71) Applicant: Samsung Display Co., Ltd., Yongin-city (KR)

(72) Inventor: Young Joo CHOI, Suwon-si (KR)

(21) Appl. No.: 14/739,295

(22) Filed: Jun. 15, 2015

(30) Foreign Application Priority Data
Jan. 5, 2015 (KR) 10-2015-0000616

(51) Int. Cl. H01L 27/12

(52) U.S. Cl. CPC H01L 27/1244

(57) ABSTRACT

A thin-film transistor (TFT) substrate including a first region including a semiconductor layer, a first etch barrier layer covering the semiconductor layer, a first contact hole and a second contact hole, which are formed through the first etch barrier layer, a source electrode, which is disposed on the first etch barrier layer and is electrically connected to the semiconductor layer via the first contact hole, a drain electrode, which is disposed on the first etch barrier layer to be isolated from the source electrode, is electrically connected to the semiconductor layer via the second contact hole and has a transparent conductive oxide layer and a metal layer, and a pixel electrode, which is disposed on the first etch barrier layer and includes the transparent conductive oxide layer.

### CROSS-REFERENCE TO RELATED APPLICATION

This application claims priority from and the benefit of Korean Patent Application No. 10-2015-0000616, filed on Jan. 5, 2015, which is hereby incorporated by reference for all purposes as if fully set forth herein.

### BACKGROUND

1. Field

Exemplary embodiments relate to a thin-film transistor (TFT) substrate.

2. Discussion of the Background

A flat-panel display (FPD) device, such as a liquid crystal display (LCD) device or an organic electroluminescent (EL) display device, includes a plurality of pairs of field-generating electrodes and an electro-optical active layer interposed between the pairs of field-generating electrodes. The LCD device includes a liquid crystal layer as the electro-optical active layer, and the organic EL display device includes an organic light-emitting layer as the electro-optical active layer.

One of every two field-generating electrodes that are paired together is connected to a conventional switching element to receive an electric signal, and the electro-optical active layer converts the electric signal into an optical signal. As a result, an image is displayed.

In the FPD device, thin-film transistors (TFTs) are used as switching elements, and signal lines, such as gate lines transmitting a scan signal for controlling the TFTs and data lines transmitting a signal to be applied to pixel electrodes, are provided.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments of the present invention provide a thin-film transistor (TFT) substrate with improved reliability and processability.

Additional aspects will be set forth in the detailed description which follows, and, in part, will be apparent from the disclosure, or may be learned by practice of the inventive concept.

An exemplary embodiment of the present invention discloses a thin-film transistor (TFT) substrate having a first region. The first region includes a semiconductor layer, a first etch barrier layer covering the semiconductor layer, a first contact hole and a second contact hole formed through the first etch barrier layer, a source electrode disposed on the first etch barrier layer and electrically connected to the semiconductor layer via the first contact hole, a drain electrode disposed on the first etch barrier layer and isolated from the source electrode, the drain electrode being electrically connected to the semiconductor layer via the second contact hole and having a transparent conductive oxide layer and a metal layer, and a pixel electrode disposed on the first etch barrier layer and including the transparent conductive oxide layer.

An exemplary embodiment of the present invention also discloses a thin-film transistor (TFT) substrate including a semiconductor layer, an etch barrier layer covering the semiconductor layer, a contact hole formed through the etch barrier layer, and a first region including the etch barrier layer having a first portion and a second portion, a height of the second portion being less than a height of the first portion. The second portion of the etch barrier layer is disposed in an area overlapping the semiconductor layer to be closer to the contact hole than the first portion of the etch barrier layer. The TFT also includes a second region including a third portion of the etch barrier layer having a third height greater than that of the second portion.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic cross-sectional view of a first region of a thin-film transistor (TFT) substrate according to an exemplary embodiment of the present invention.

FIG. 2 is a schematic cross-sectional view of a second region of the TFT substrate of FIG. 1.

FIG. 3 is a schematic cross-sectional view of a third region of the TFT substrate of FIG. 1.

FIGS. 4 to 21 are schematic cross-sectional views illustrating the fabrication of the TFT substrate of FIG. 1.

FIG. 22 is a schematic cross-sectional view illustrating the fabrication of a first region of a TFT substrate according to another exemplary embodiment of the invention.

FIG. 23 is a schematic cross-sectional view of the first region of the TFT substrate of FIG. 22.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

Exemplary embodiments will hereinafter be described with reference to the accompanying drawings.

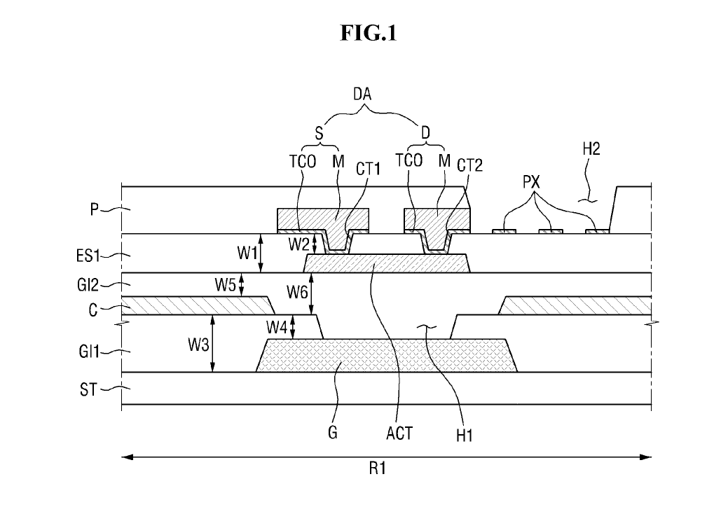

FIG. 1 is a schematic cross-sectional view of a first region R1 of a thin-film transistor (TFT) substrate according to an exemplary embodiment of the present invention.

Referring to FIG. 1, the first region R1 may include an insulating substrate ST, a gate wire G, a first gate insulating layer GI1, a common electrode C, a second gate insulating layer GI2, a semiconductor layer ACT, a first etch barrier layer ES1, a data wire DA, a passivation layer P, and a pixel electrode PX.

The semiconductor layer ACT may be disposed on the second gate insulating layer GI2. The semiconductor layer ACT may be disposed in an area overlapping the gate wire G. The semiconductor layer ACT may be an oxide semiconductor layer. In a non-limiting example, the semiconductor layer ACT may include at least one of zinc (Zn), titanium (Ti), indium (In), tin (Sn), gallium (Ga) and hafnium (Hf). In another non-limiting example, the semiconductor layer ACT may include indium gallium zinc oxide (IGZO) or indium tin zinc oxide (ITZO).

The first etch barrier layer ES1 may cover part of the semiconductor layer ACT. The first etch barrier layer ES1 may be formed as a double layer of silicon nitride (SiNₓ) or SiNₓ/silicon oxide (SiOₓ). The first etch barrier layer ES1 may have height portion 1 with a height W1 and height portion 2 with a height W2, which is less than the height W1. Height portion 2 may be formed in an area overlapping the semiconductor layer ACT.

A first contact hole CT1 and a second contact hole CT2 may be formed in the first etch barrier layer ES1. The first contact hole CT1 and the second contact hole CT2 may be formed through the first etch barrier layer ES1. The first contact hole CT1 and the second contact hole CT2 may be formed in the area overlapping the semiconductor layer ACT. In a non-limiting example, the first contact hole CT1 and the second contact hole CT2 may be formed through height portion 2. The semiconductor layer ACT may be partially exposed between parts of the first etch barrier layer ES1 through the first contact hole CT1 and the second contact hole CT2. The semiconductor layer ACT may be electrically connected to the data wire DA via the first contact hole CT1 and the second contact hole CT2.

The data wire DA may include a metal layer M and a transparent conductive oxide layer TCO. The data wire DA may be disposed on the first etch barrier layer ES1. The data wire DA may include a source electrode S and a drain electrode D. The source electrode S may be electrically connected to the semiconductor layer ACT via the first contact hole CT1, and the drain electrode D may be electrically connected to the semiconductor layer ACT via the second contact hole CT2. The source electrode S may be disposed on the semiconductor layer ACT and the first etch barrier layer ES1, and the drain electrode D may also be disposed on the semiconductor layer ACT and the first etch barrier layer ES1. The source electrode S and the drain electrode D may be isolated from each other above the first etch barrier layer ES1 with height portion 2 of the first etch barrier layer ES1 interposed therebetween. Part of height portion 2 of the first etch barrier layer ES1 may be exposed between the source electrode S and the drain electrode D. The part of height portion 2 exposed between the source electrode S and the drain electrode D may be covered by the passivation layer P, which will be described later in detail.

The transparent conductive oxide layer TCO may be disposed on the first etch barrier layer ES1 and the semiconductor layer ACT, and may contact part of the first etch barrier layer ES1 and part of the semiconductor layer ACT. The transparent conductive oxide layer TCO may prevent metal ions in the metal layer M from diffusing into the semiconductor layer ACT. That is, the transparent conductive oxide layer TCO may serve as a diffusion barrier layer for metal ions.

In a non-limiting example, the transparent conductive oxide layer TCO may include a bare zinc oxide (ZnO) layer, a gallium zinc oxide (GZO) layer, an aluminum zinc oxide (AZO) layer, or an indium zinc oxide (IZO) layer.

In the non-limiting example, the GZO layer may contain 77.2% to 94.4% by weight of ZnO and 5.6% to 22.8% by weight of Ga. The GZO layer with the Ga or gallium oxide (Ga₂O₃) content set forth herein may prevent an undercut such that the transparent conductive oxide layer TCO may serve as a diffusion barrier layer; may prevent any tailing that may occur in the transparent conductive oxide layer TCO during etching; and may prevent a short at the boundary with the semiconductor layer ACT.

In the non-limiting example, the AZO layer may contain 50 mol % to 97.5 mol % of zinc oxide (ZnO) and 2.5 mol % to 50 mol % of Al. The AZO layer with the Al or aluminum oxide (Al₂O₃) content range set forth herein may prevent an undercut such that the transparent conductive oxide layer TCO may serve as a diffusion barrier layer; may prevent any tailing that may occur in the transparent conductive oxide layer TCO during etching; and may prevent a short at the boundary with the semiconductor layer ACT.

In the non-limiting example, the IZO layer may contain 10% to 97.5% by weight of ZnO and 2.5% to 90% by weight of In. Alternatively, the IZO layer may contain 60% to 80% by weight of ZnO and 20% to 40% by weight of In. The IZO layer with the In or indium oxide (In₂O₃) content ranges set forth herein may prevent an undercut such that the transparent conductive oxide layer TCO may serve as a diffusion barrier layer; may prevent any tailing that may occur in the transparent conductive oxide layer TCO during etching; and may prevent a short at the boundary with the semiconductor layer ACT.

The metal layer M may serve as a main wiring layer transmitting a data signal. The metal layer M may contact the transparent conductive oxide layer TCO. In a non-limiting example, the metal layer M may be formed of nickel (Ni), cobalt (Co), Ti, silver (Ag), copper (Cu), molybdenum (Mo), aluminum (Al), beryllium (Be), niobium (Nb), gold (Au), or iron (Fe).

Another transparent conductive oxide layer TCO (not illustrated) may be additionally provided on the metal layer M. The additional transparent conductive oxide layer TCO may serve as a capping layer preventing the oxidation of the metal layer M. The additional transparent conductive oxide layer TCO may include a bare ZnO layer, a GZO layer, an AZO layer, or an IZO layer, as already mentioned above. The additional transparent conductive layer provided as a capping layer may have a higher etching rate than the transparent conductive oxide layer TCO provided as a diffusion barrier layer.

In a non-limiting example, the GZO layer provided as a capping layer may contain 70% to 85% by weight of ZnO and 15% to 30% by weight of Ga, the AZO layer provided as a capping layer may contain 70% to 85% by weight of ZnO and 15% to 30% by weight of Al, and the IZO layer provided as a capping layer may contain 70% to 85% by weight of ZnO and 15 to 30% by weight of In.

The passivation layer P may cover the first etch barrier layer ES1, the source electrode S, and the drain electrode D. The passivation layer P may be formed of an inorganic insulating material, such as SiNₓ or SiOₓ; an organic insulating material; or a low dielectric constant insulating material. The passivation layer P may include a first passivation layer (not illustrated) and a second passivation layer (not illustrated). In a non-limiting example, the first passivation layer may be formed of silicon oxide, and the second passivation layer may be formed of silicon nitride. A second through-hole H2 may be formed in the passivation layer P. Part of the first etch barrier layer ES1 may be exposed through the second through-hole H2, and the pixel electrode PX may be disposed on the part of the first etch barrier layer ES1 exposed by the second through-hole H2.

The pixel electrode PX may be formed of the transparent conductive oxide layer TCO that forms the data wire DA. The pixel electrode PX may receive a data voltage from the drain electrode D. The pixel electrode PX may be disposed on the first etch barrier layer ES1. The pixel electrode PX may include a plurality of incision patterns that are formed by the transparent conductive oxide layer TCO and are isolated from one another on the first etch barrier layer ES1. The pixel electrode PX may be disposed in a pixel region (not illustrated), which is defined by the gate wire G and the data wire DA intersecting each other. A plurality of pixel regions may be disposed in a matrix, and a plurality of data wires including the data wire DA, a plurality of gate wires including the gate wire G, and the intersections between the plurality of data wires and the plurality of gate wires may be disposed among the plurality of pixel regions.

The insulating substrate ST, the gate wire G, the first gate insulating layer GI1, the common electrode C, and the second gate insulating layer GI2 will hereinafter be sequentially described.

The insulating substrate ST may be formed of transparent glass or a synthetic resin.

The gate wire G may transmit a gate signal. The gate wire G may be disposed on the insulating substrate ST. The gate wire G may include a gate line, which extends over the insulating substrate ST in a direction perpendicular to a direction in which the data wire DA extends, and a gate electrode, which protrudes from the gate line toward the pixel electrode PX. The gate wire G of FIG. 1 may be the gate electrode. The gate wire G may be formed in the area overlapping the semiconductor layer ACT.

The gate wire G may be formed of an Ag-based metal such as Al or an Al alloy, an Ag-based metal such as Ag or an Ag alloy, a Cu-based metal such as Cu or a Cu alloy, a Mo-based metal such as Mo, or a Mo alloy, chromium (Cr), Ti or tantalum (Ta), but the invention is not limited thereto. In a non-limiting example, the gate wire G may be formed as a double layer of Ti/Cu.

The first gate insulating layer GI1 may be disposed on the insulating substrate ST and the gate wire G. The first gate insulating layer GI1 may be formed as a double layer of SiNₓ or SiNₓ/SiOₓ. The first gate insulating layer GI1 may include height portion 3 with a height W3 and height portion 4 with a height W4, which is greater than the height W3. Height portion 4 may be disposed in the area overlapping the gate wire G.

The first gate insulating layer GI1 may cover part of the gate wire G. A first through-hole H1 may be formed in the first gate insulating layer GI1. Height portion 4 may be disposed closer than height portion 3 to the first through-hole H1. The first through-hole H1 may be formed through the first gate insulating layer GI1. The first through-hole H1 may be formed in height portion 4, and the gate wire G may be partially exposed through the first through-hole H1. Part of the gate wire G may be protected by the second gate insulating layer GI1 through the first through-hole H1. The first through-hole H1 may be filled with a material that forms the second gate insulating layer GI2.

The common electrode C may be disposed on the first gate insulating layer GI1. In a non-limiting example, the common electrode C may be disposed mostly over height portion 3 of the first gate insulating layer GI1. A first portion of the common electrode C may be isolated from a second portion of the common electrode C with the first through-hole H1 interposed therebetween. The common electrode C may be disposed in an area overlapping the pixel electrode PX. The common electrode C, which is in the area overlapping the pixel electrode PX, may be formed in the shape of a plate. The common electrode C may form a fringe field with the pixel electrode PX, thereby generating vertical and horizontal electric fields. In a non-limiting example, the common electrode C may be formed of a transparent conductive oxide, such as ITO or IZO.

The common electrode C may be covered by the second gate insulating layer GI2. The second gate insulating layer GI2 may cover part of the first gate insulating layer GI1 and part of the gate wire G. The second gate insulating layer GI2 may be formed as a double layer of SiNₓ or SiNₓ/SiOₓ. The second gate insulating layer GI2 may include height portion 5 with a height W5 and height portion 6 with a height W6, which is greater than the height W5. Height portion 5 may be disposed in an area overlapping the common electrode C, and height portion 6 may be disposed closer than height portion 5 to the first through-hole H1. Height portion 6 may fill the first through-hole H1. The semiconductor layer ACT may be disposed on the second gate insulating layer GI2.

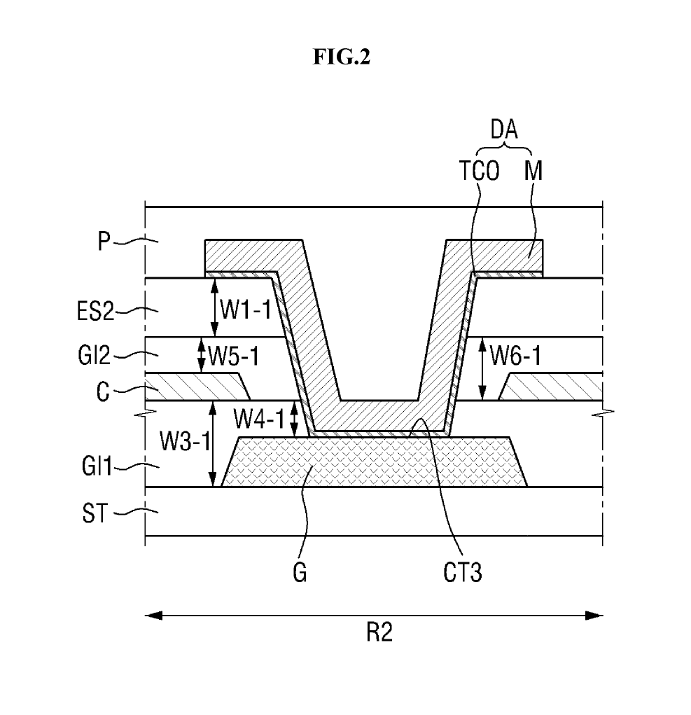

FIG. 2 is a schematic cross-sectional view of a second region R2 of the TFT substrate according to the exemplary embodiment of FIG. 1.

Referring to FIG. 2, the second region R2 may include an insulating substrate ST, a gate wire G, a first gate insulating layer GI1, a common electrode C, a second gate insulating layer GI2, a semiconductor layer ACT, a second etch barrier layer ES2, a data wire A, and a passivation layer P.

The elements and the structures of the second region R2 will hereinafter be described, focusing mainly on differences with those of the first region R1.

The second region R2 differs from the first region R1 in that in the second region R2, no pixel electrode PX is disposed on the second etch barrier layer ES2. The second region R2 also differs from the first region R1 in that in the second region R2, no second through-hole H2 for receiving the pixel electrode PX therein is formed in the passivation layer P. Because no semiconductor layer ACT is disposed on the second etch barrier layer ES2, the second etch barrier layer ES2 includes only one height portion, i.e., height portion 1-1 with a height W1-1, and thus, differs from the first etch barrier layer ES1 of FIG. 1, which includes both height portion 1 and height portion 2.

The second region R2 also differs from the first region R1 in that in the second region R2, a third contact hole CT3 is formed through the second etch barrier layer ES2, the second gate insulating layer GI2 and the first gate insulating layer GI1, whereas in the first region R1, the first through-hole H1 is formed only through the first gate insulating layer GI1. The first portion of common electrode C may be isolated from a neighboring second portion of common electrode C with the third contact hole CT3 interposed therebetween, whereas the first portion of common electrode C of FIG. 1 is isolated from a neighboring second portion of common electrode C with the first through-hole H1 interposed therebetween.

The second region R2 also differs from the first region R1 in that in the second region R2, the gate wire G and the data wire DA are electrically connected to each other via the third contact hole CT3, whereas in the first region R1, the first through-hole H1 is filled with the second gate insulating layer GI2 and the data wire DA and the semiconductor layer ACT are electrically connected to each other via the first and second contact holes CT1 and CT2.

More specifically, referring to FIG. 2, the first gate insulating layer GI1 may be disposed on the insulating substrate ST and the gate wire G. The first gate insulating layer GI1 in the second region R2 may include height portion 3-1 with a height W3-1 and height portion 4-1 with a height W4-1, which is greater than the height W3-1. Height portion 4-1 may be disposed in an area overlapping the gate wire G. Height portion 4-1 may be disposed closer than height portion 3-1 to the third contact hole CT3. The second gate insulating layer GI1 in the second region R2 may include height portion 5-1 with a height W5-1 and height portion 6-1 with a height W6-1, which is less than the height W5-1. Height portion 6-1 may be disposed closer than height portion 5-1 to the third contact hole CT3.

The gate wire G may be formed by forming a gate wire material layer (not illustrated) on the insulating substrate ST in the shape of a plate and patterning the gate wire material layer in the first region R1, the second region R2 and a third region R3, respectively, and the first gate insulating layer GI1 may then be formed to cover the insulating substrate St and the gate wire G. Accordingly, in a non-limiting example, the height W3 of height portion 3 of FIG. 1 and the height W3-1 of height portion 3-1 of FIG. 2 may be substantially the same, the height W4 of height portion 4 and the height W4-1 of height portion 4-1 may be substantially the same, the height W5 of height portion 5 and the height W5-1 of height portion 5-1 may be substantially the same, and the height W6 of height portion 6 and the height W6-1 of height portion 6-1 may be substantially the same. However, the present invention is not limited to this example.

Similarly, the height W1-1 of height portion 1-1 of FIG. 2 may be substantially to the same as the height W1 of height portion 1 of FIG. 1 because the common electrode C, the second gate insulating layer GI2, the second etch barrier layer ES2, and the passivation layer P in the second region R2 are formed by the same processes as the common electrode C, the second gate insulating layer GI2, the first etch barrier layer ES1, and the passivation layer P in the first region R1.

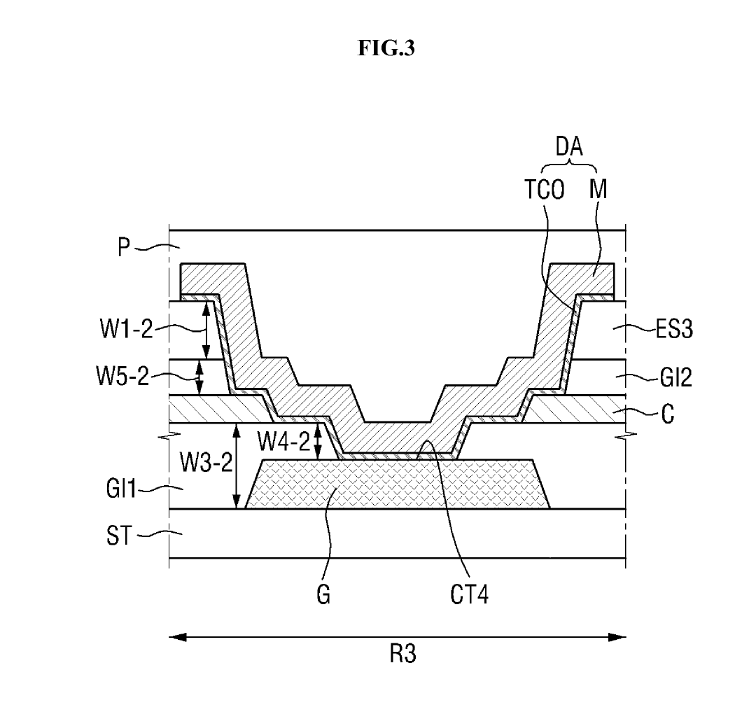

FIG. 3 is a schematic cross-sectional view of a third region R3 of the TFT substrate according to the exemplary embodiment of FIG. 1.

Referring to FIG. 3, the third region R3 may include an insulating substrate ST, a gate wire G, a first gate insulating layer GI1, a common electrode C, a second gate insulating layer GI2, a semiconductor layer ACT, a third etch barrier layer ES3, a data wire DA, and a passivation layer P.

The elements and the structures of the third region R3 will hereinafter be described, focusing mainly on differences with those of the first region R1.

The third region R3 differs from the first region R1 in that in the third region R3, no pixel electrode PX is disposed on the third etch barrier layer ES3. The third region R3 differs from the first region R1 in that in the third region R3, no second through-hole H2 for receiving the pixel electrode PX therein is formed in the passivation layer P. Because no semiconductor layer ACT is disposed on the third etch barrier layer ES3, the second etch barrier layer ES2 includes only one height portion, i.e., height portion 1-2 with a height W1-2, and thus, differs from the first etch barrier layer ES1 of FIG. 1, which includes both height portion 1 and height portion 2.

The third region R3 differs from the first region R1 in that in the third region R3, a fourth contact hole CT4 is formed through the third etch barrier layer ES3, the second gate insulating layer GI2 and the first gate insulating layer GI1, whereas in the first region R1, the first through-hole H1 is formed only through the first gate insulating layer GI1. A first portion of common electrode C may be isolated from a neighboring second portion of common electrode C with the fourth contact hole CT4 interposed therebetween, whereas the first portion of common electrode C of FIG. 1 is isolated from the neighboring second portion of common electrode C with the first through-hole H1 interposed therebetween.

The third region R3 also differs from the first region R1 in that in the third region R3, the gate wire G and the data wire DA are electrically connected to each other via the fourth contact hole CT4, whereas in the first region R1, the first through-hole H1 is filled with the second gate insulating layer GI2 and the data wire DA and the semiconductor layer ACT are electrically connected to each other via the first and second contact holes CT1 and CT2.

The elements and the structures of the third region R3 will hereinafter be described in further detail, focusing mainly on differences with those of the second region R2.

The third region R3 differs from the second region R2 in that in the third region R3, the second gate insulating layer GI2 covers only part of the common electrode C, whereas in the first second region R2, the second gate insulating layer GI2 covers the entire common electrode C. The third region R3 also differs from the second region R2 in that in the third region R3, the data wire DA is electrically connected to both the common electrode C and the gate wire G, whereas in the second region R2, the data wire DA is electrically connected only to the gate wire G and is insulated from the common electrode C by the second gate insulating layer GI2.

Referring to FIG. 3, the first gate insulating layer GI1 may be disposed on the insulating substrate ST and the gate wire G. The first gate insulating layer GI1 in the third region R3 may include height portion 3-2 with a height W3-2 and height portion 4-2 with a height W4-2. Height portion 4-2 may be disposed in an area overlapping the gate wire G. Height portion 4-2 may be disposed closer than height portion 3-2 to the fourth contact hole CT4. The second gate insulating layer GI2 in the third region R3 may include height portion 5-2 with a height W5-2.

In a non-limiting example, the height W3-1 of height portion 3-1 of FIG. 2 and the height W3-2 of height portion 3-2 of FIG. 3 may be substantially the same, the height W4-1 of height portion 4-1 of FIG. 2 and the height W4-2 of height portion 4-2 of FIG. 3 may be substantially the same, and the height W5-1 of height portion 5-1 of FIG. 2 and the height W5-2 of height portion 5-2 of FIG. 3 may be substantially the same. However, the invention is not limited to this example. The height W1-2 of height portion 1-2 of FIG. 3 may be substantially to the same as the height W1-1 of height portion 1-1 of FIG. 2.

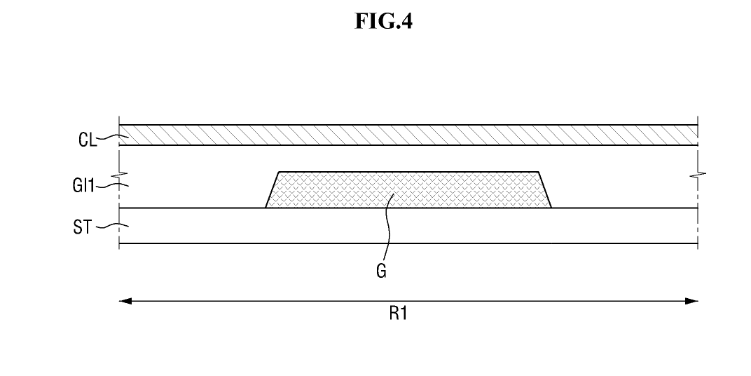

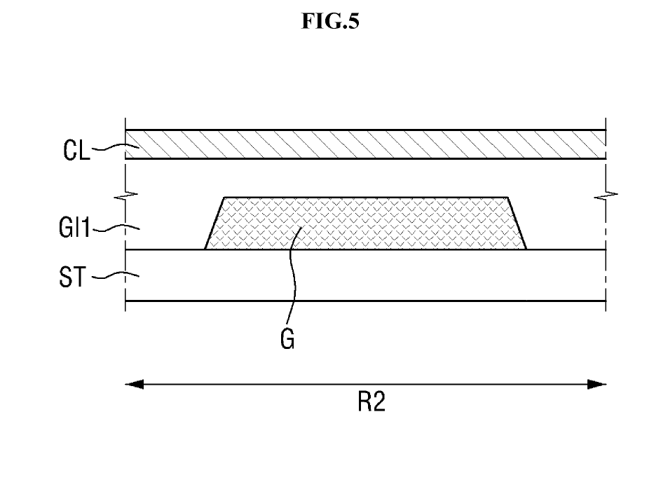

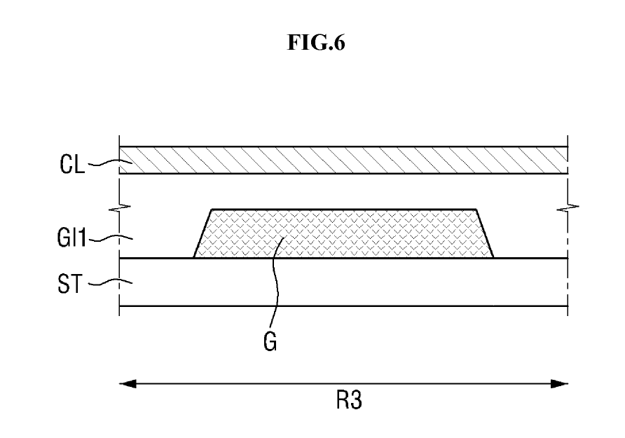

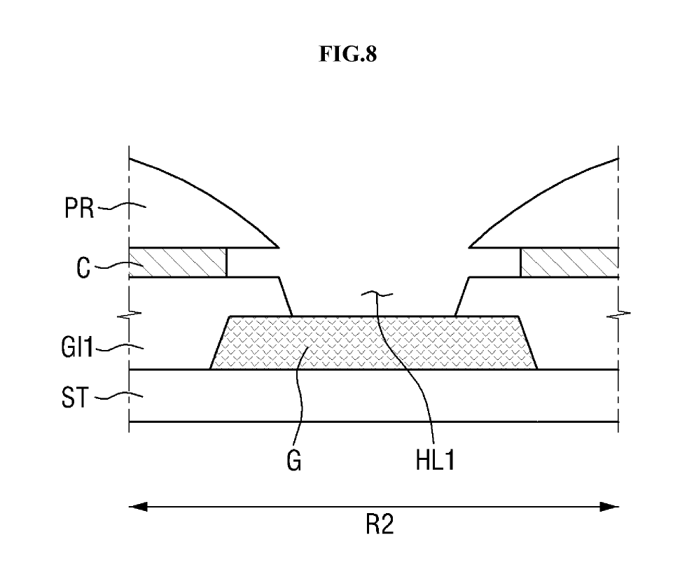

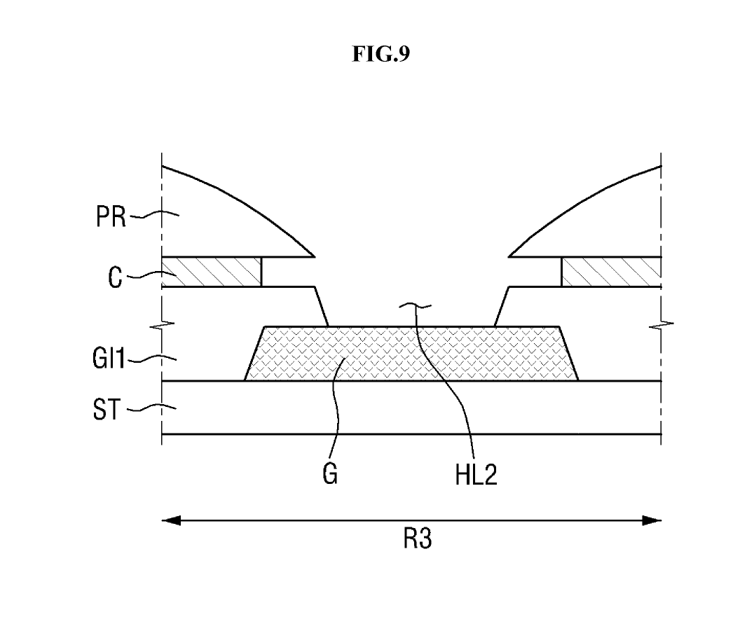

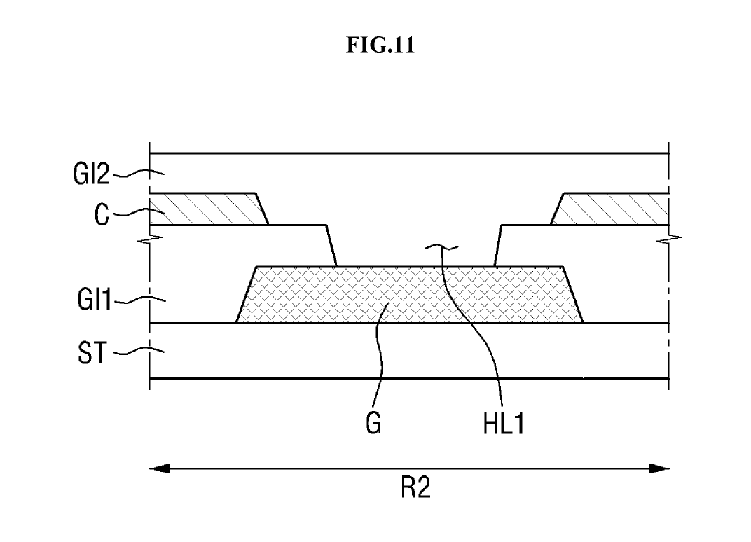

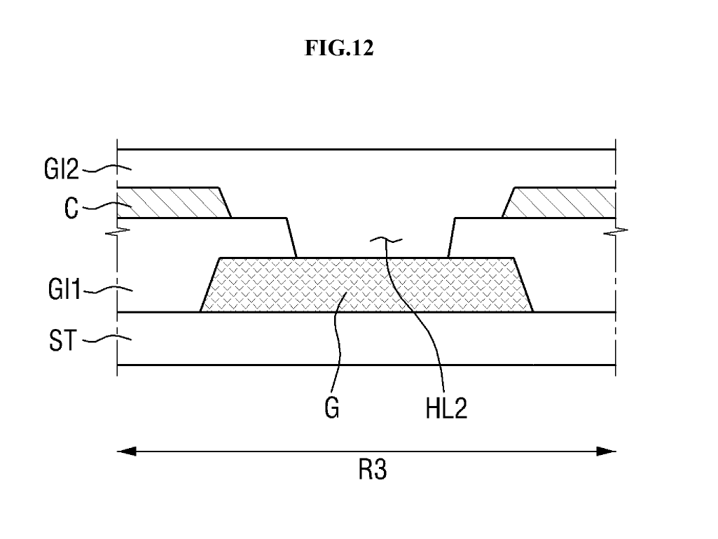

FIGS. 4 to 21 are schematic cross-sectional views illustrating the fabrication of the TFT substrate according to the exemplary embodiment of FIG. 1.

Referring to FIGS. 4 to 6, in each of first, second and third regions R1, R2 and R3, a gate wire G may be formed on an insulating substrate ST. As mentioned above, the gate wire G may be formed by forming a gate wire material layer (not illustrated) on the insulating substrate ST in the shape of a plate and patterning the gate wire material layer in the first, second, and third regions R1, R2 and R3, respectively, using a mask (not illustrated).

In each of the first, second, and third regions R1, R2, and R3, a first gate insulating layer GI1 may be formed to cover the gate wire G and the insulating substrate ST. That is, the first gate insulating layer GI1 may be formed on the gate wire G and the insulating substrate ST. The first gate insulating layer GI1 may be a planarization layer. A common electrode material layer CL may be formed on the first gate insulating layer GI1. The common electrode material layer CL may be formed in the shape of a plate to cover the entire first gate insulating layer GI1.

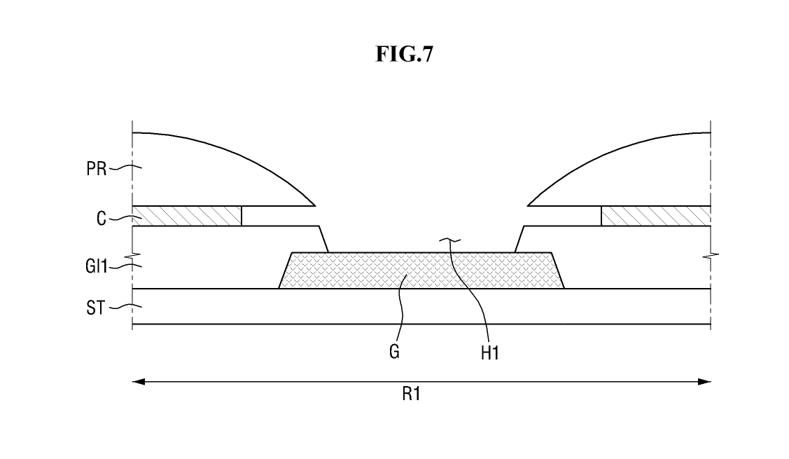

Referring to FIGS. 7 to 9, in each of the first, second, and third regions R1, R2, and R3, a first portion of common electrode C may be formed on the first gate insulating layer GI1 to be isolated from a second portion of common electrode C with a through-hole H1, HL1, or HL2 interposed therebetween. The common electrode C may be formed by photolithography. Some of the common electrode material layer CL of FIGS. 4 to 6 may be removed by wet etching thereby patterning the common electrode C.

More specifically, part of the common electrode material layer CL of FIG. 4, 5, or 6, and part of the first gate insulating layer GI1 may be removed from an area not protected by photoresist PR. As a result, the common electrode C may be formed, part of the first gate insulating layer GI1 may be exposed, and the through-hole H1, HL2, or HL2 may be formed in the first gate insulating layer GI1.

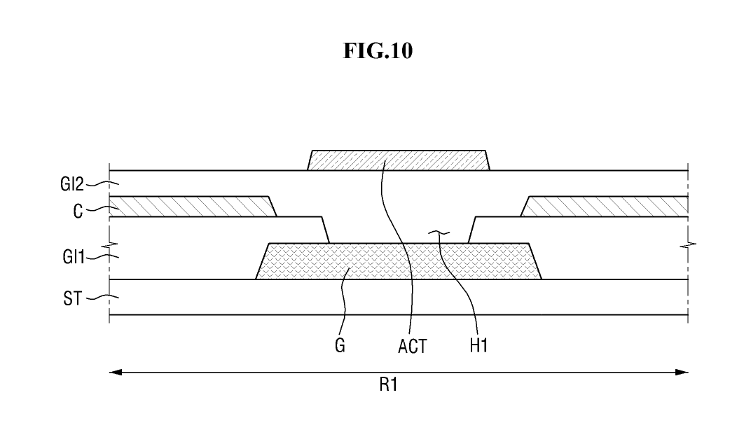

Referring to FIGS. 10 to 12, in each of the first, second, and third regions R1, R2, and R3, a second gate insulating layer GI2 may be formed to cover the gate wire G, part of the first gate insulating layer GI1 and the common electrode C. The second gate insulating layer Gi2 may fill the through-hole H1, HL1 or HL2.

Referring to FIG. 10, in the first region R1, a semiconductor layer ACT may be selectively formed on the second gate insulating layer GI2. The semiconductor layer ACT may be formed by forming a semiconductor material layer (not illustrated) on the second gate insulating layer GI2, and patterning the semiconductor material layer through wet etching.

In the second and third regions R2 and R3, unlike in the first region R1, no semiconductor layer ACT is formed on the second gate insulating layer GI2.

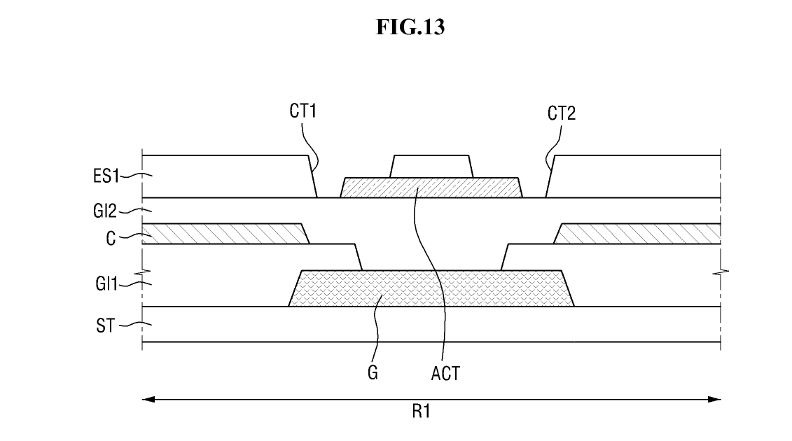

Referring to FIGS. 13 to 15, in each of the first, second, and third regions R1, R2, and R3, a first, second or third etch barrier layer ES1, ES2, or ES3 may be formed on the second gate insulating layer GI2.

Before the formation of the first, second, or third etch barrier layer ES1, ES2, or ES3, dry etching may be performed on the entire surface of the second gate insulating layer GI2. During the dry etching process, the semiconductor layer ACT is not etched. Accordingly, part of the second gate insulating layer GI2 not protected by the semiconductor layer ACT may be partially removed, and as a result, part of the second gate insulating layer GI2 located below the semiconductor layer ACT may protrude beyond the part of the second gate insulating layer GI2 not protected by the semiconductor layer ACT. That is, a height difference may be generated between the part of the second gate insulating layer GI2 not protected by the semiconductor layer ACT and the part of the second gate insulating layer GI2 protected by the semiconductor layer ACT, and the top surface of the part of the second gate insulating layer GI2 protected by the semiconductor layer ACT may be located higher than the top surface of the part of the second gate insulating layer GI2 not protected by the semiconductor layer ACT.

Referring to FIG. 13, the first etch barrier layer ES1 may be formed on the semiconductor layer ACT and the second gate insulating layer GI2, and in an area overlapping the semiconductor layer ACT, a first contact hole CT1 and a second contact hole CT2 may be formed.

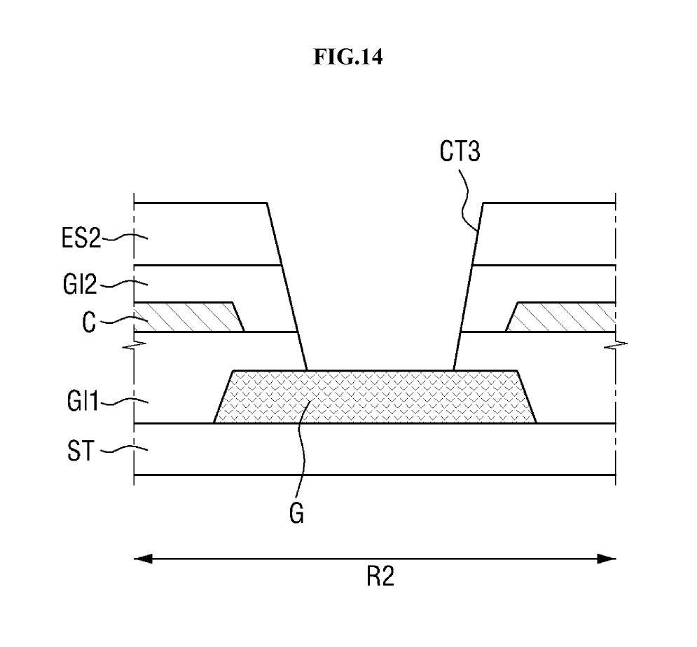

Referring to FIG. 14, the second etch barrier layer ES2 may be formed on the second gate insulating layer GI2, and in an area overlapping the gate wire G, a third contact hole CT3 may be formed through the second etch barrier layer ES2, the second gate insulating layer GI2, and the first etch barrier layer GI1.

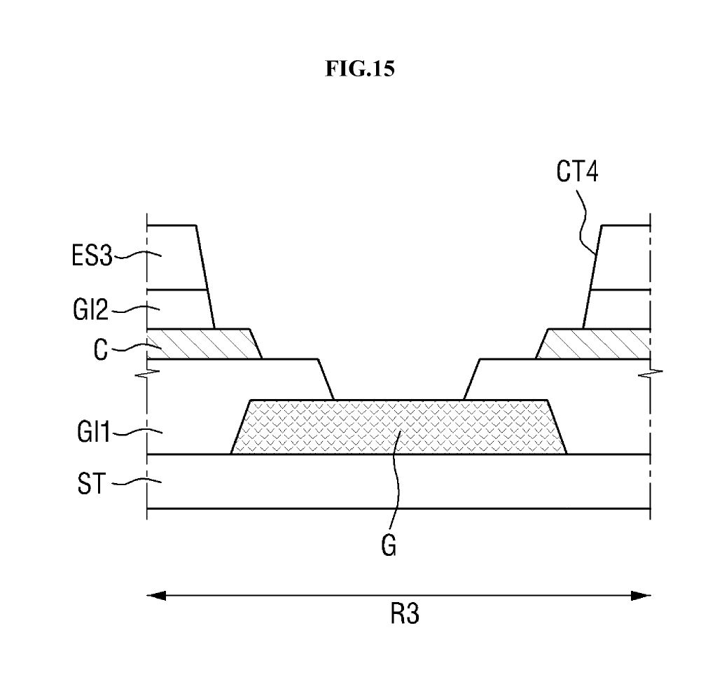

Referring to FIG. 15, the third etch barrier layer ES3 may be formed on the second gate insulating layer GI2, and in an area overlapping the gate wire G, a fourth contact hole CT4 may be formed through the second etch barrier layer ES2, the second gate insulating layer GI2, and the first etch barrier layer GI1. The fourth contact hole CT4 is formed to expose part of the common electrode C therethrough, and thus, differs from the third contact hole CT3, which does not expose the common electrode C because the common electrode C is formed to be covered by the second gate insulating layer GI2.

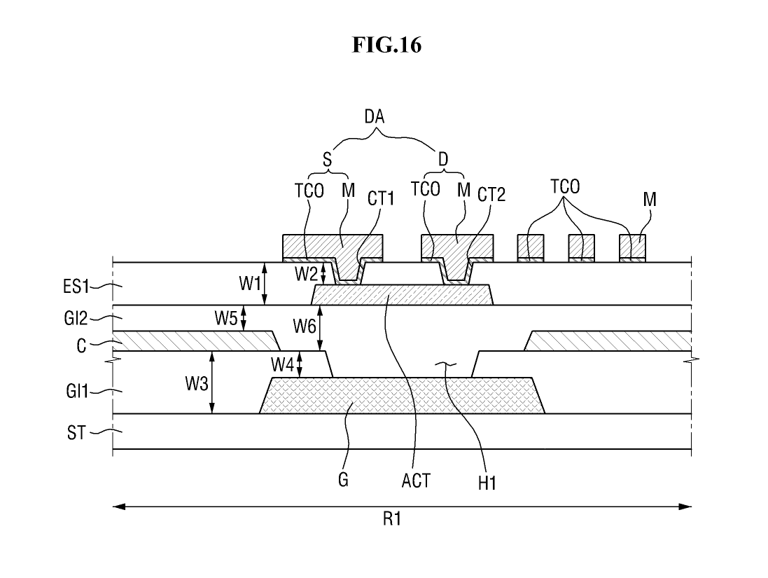

Referring to FIGS. 16 to 18, in each of the first, second, and third regions R1, R2, and R3, a data wire may be formed on the first, second, or third etch barrier layer ES1, ES2, or ES3. The data wire DA may be electrically connected to the semiconductor layer ACT and the gate wire G via the first through fourth contact holes CT1 through CT4. The first region R1 differs from the second region R2 or the third region R3 in that in the first region R1, the data wire DA is electrically connected to the semiconductor layer ACT via the first and second contact holes CT1 and CT2, whereas in the second region R2, the data wire DA is electrically connected to the gate wire G via the third contact hole CT3 and in the third region R3, the data wire DA is electrically connected to the gate wire G and the common electrode C via the fourth contact hole CT3.

Referring to FIGS. 1, 16, and 19, in the first region R1, the data wire DA may form a source electrode S, a drain electrode D, and pixel electrode forming portions, which are isolated from one another over the first etch barrier layer ES1. In a region where a pixel electrode PX is to be formed, the pixel electrode forming portions may be formed by the data wire DA, which includes a metal layer M and a transparent conductive oxide layer TCO, and may be isolated from one another.

The pixel electrode PX may include the transparent conductive oxide layer TCO of the data wire DA, but does not include the metal layer M of the data wire DA.

The source electrode S and the drain electrode D may be isolated from each other with height portion 2 of the first etch barrier layer ES1 interposed therebetween, and on an outer side of the drain electrode D, the pixel electrode PX may be disposed in an area overlapping the common electrode C to be isolated from the drain electrode D.

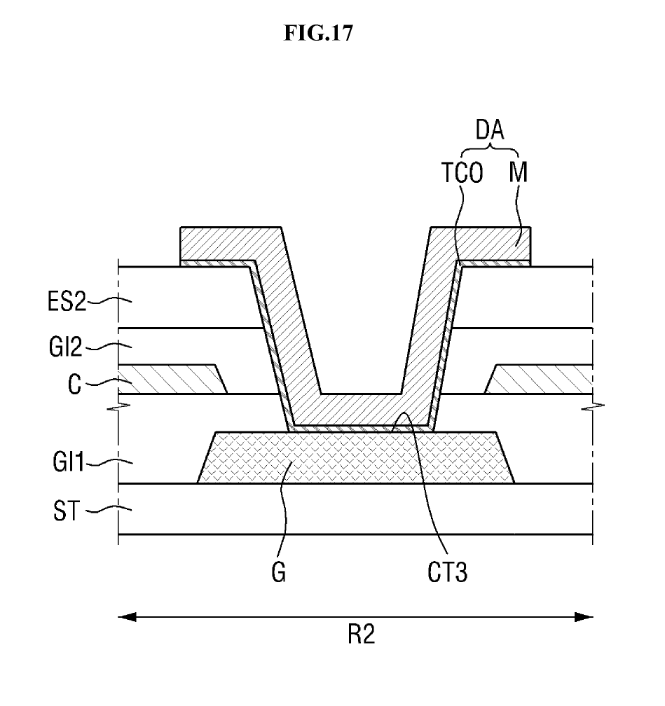

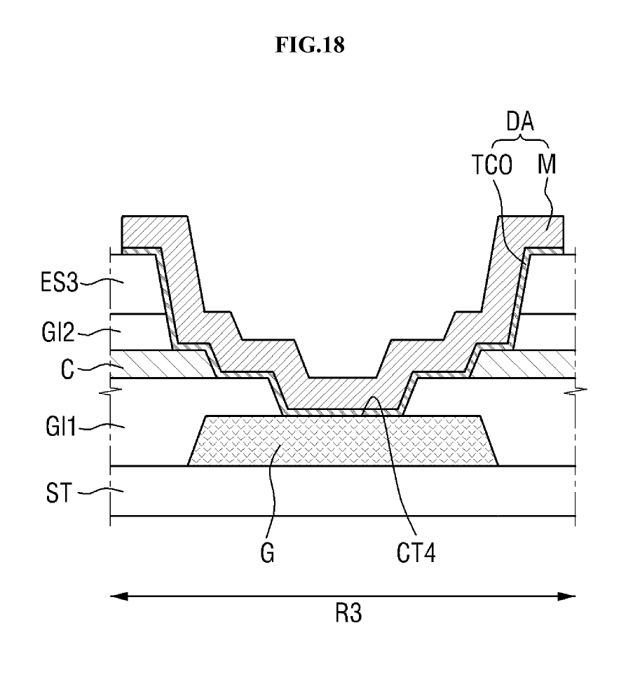

Referring to FIGS. 17 and 18, the data wire DA, which is formed on the second or third etch barrier layer ES2 or ES3, may be received in the third or fourth contact hole CT3 or CT4, and part of the second or third etch barrier layer ES2 or ES3 may be covered by the data wire DA.

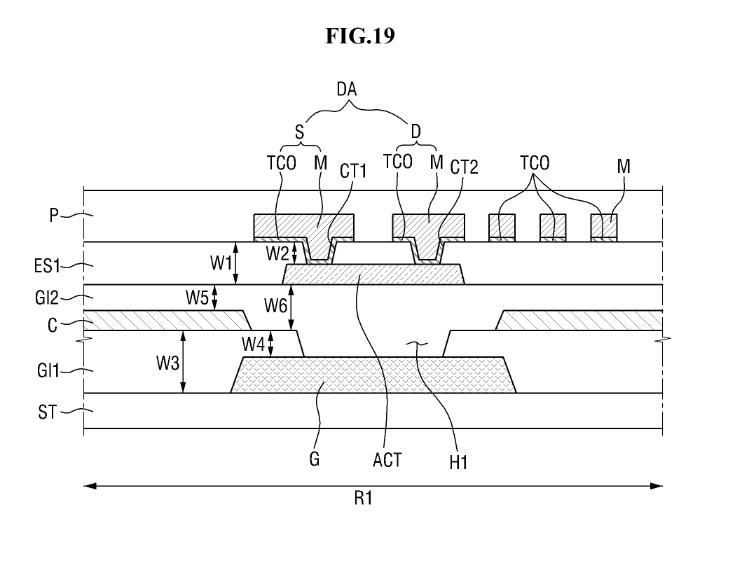

Referring to FIGS. 19 to 21, a passivation layer P may be formed on the data wire DA and the first, second, or third etch barrier layer ES1, ES2, or ES3 to cover the data wire DA and the first, second or third etch barrier layer ES1, ES2 or ES3. The passivation layer P may be a planarization layer.

After the process illustrated in FIG. 19, the passivation layer P and the metal layer M of the data wire DA may be removed from the pixel electrode forming portions through wet etching, thereby forming a second through-hole H2 and the pixel electrode PX of FIG. 1, which consists of the transparent conductive oxide layer TCO. Accordingly, the formation of the first region R1 of the TFT transistor substrate according to the exemplary embodiment of FIG. 1 may be completed.

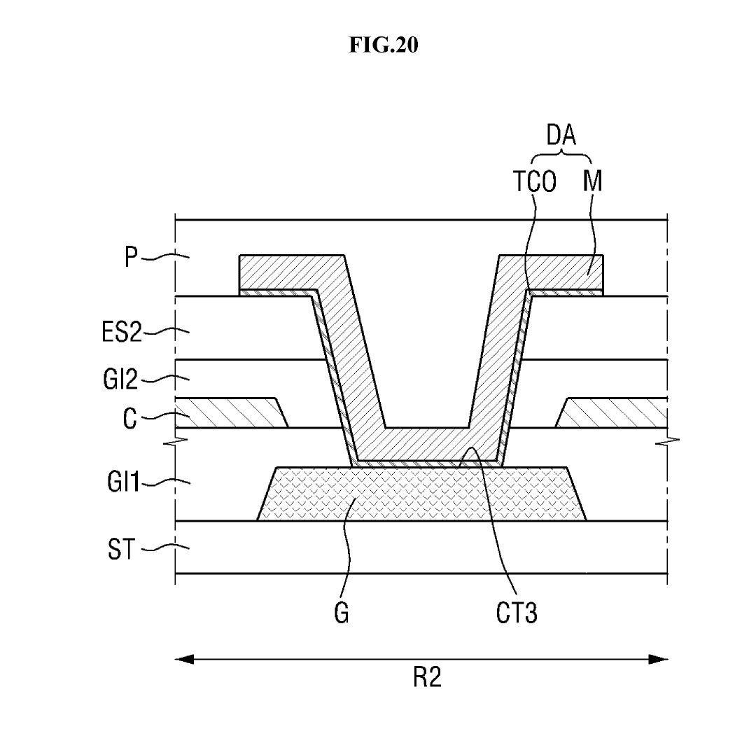

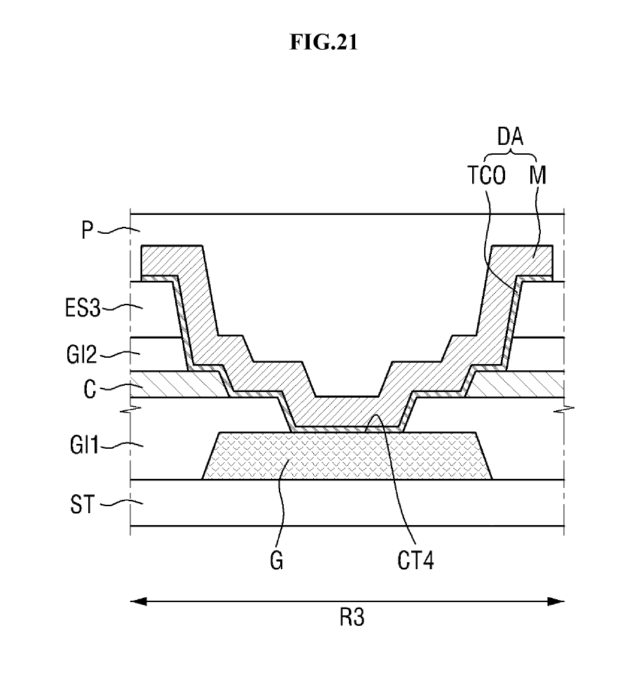

After the processes illustrated in FIGS. 20 and 21, no further processes may be performed in the second and third regions R2 and R3. That is, the formation of the second and third regions R2 and R3 of the TFT transistor substrate according to the exemplary embodiment of FIG. 1 may be completed by the processes of FIGS. 20 and 21.

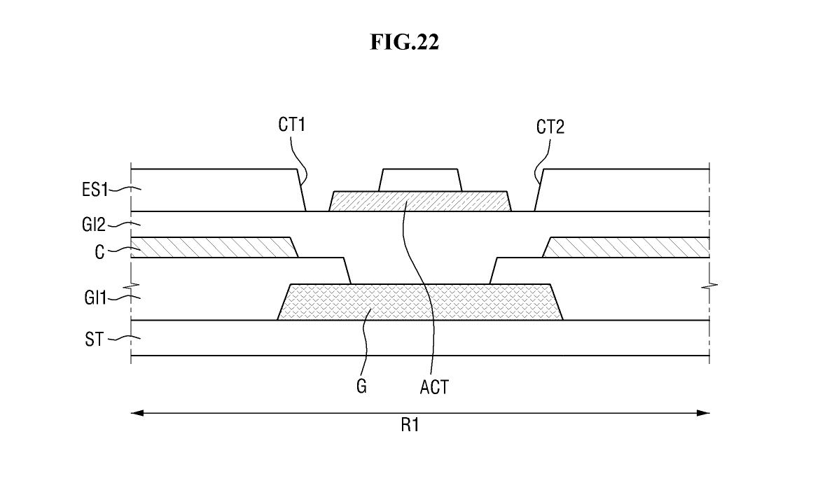

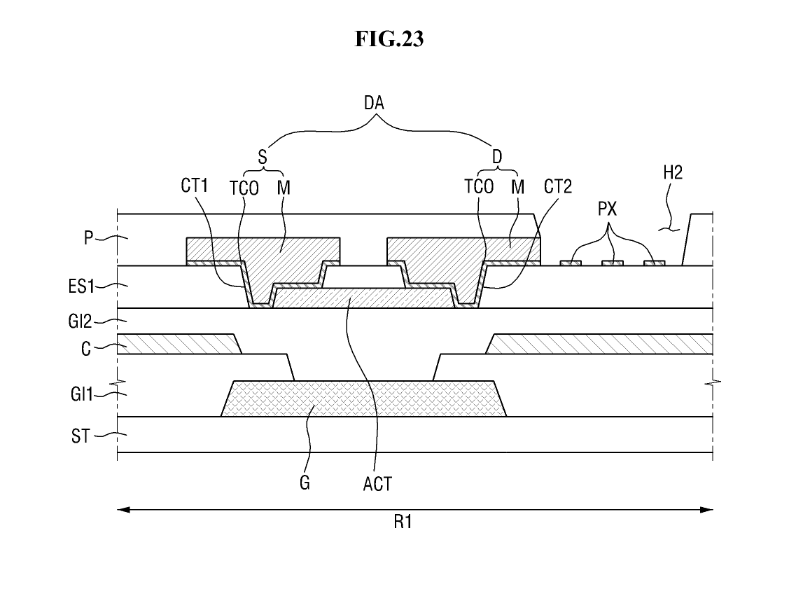

FIG. 22 is a schematic cross-sectional view illustrating the fabrication of a first region R1 of a TFT substrate according to another exemplary embodiment of the invention. FIG. 23 is a schematic cross-sectional view of the first region R1 of the TFT substrate according to the exemplary embodiment of FIG. 22.

The first region R1 of FIG. 22 is the same as the first region R1 of FIG. 1 except that in the first region R1 of FIG. 22, a first contact hole CT1 and a second contact hole CT2 are formed to completely expose both ends of a semiconductor layer ACT. In a non-limiting example, part of a first etch barrier layer ES1 may be removed using a halftone mask (not illustrated) so as to expose both ends of the semiconductor layer ACT.

Referring to FIG. 23, the first region R1 of FIG. 22 is the same as the first region R1 of FIG. 1 except that in the first region R1 of FIG. 22, a source electrode S and a drain electrode D are each formed to correspond to both a second gate insulating layer GI2 and a semiconductor layer ACT via a first contact hole CT1 and a second contact hole CT2, respectively, whereas in the first region R1 of FIG. 1, the source electrode S and the drain electrode D are each formed to correspond only to the semiconductor layer ACT via the first contact hole CT1 and the second contact hole CT2, respectively.

In the present invention, it is possible to improve reliability and to increase safety in processability of a TFT substrate by using an etch barrier layer. It is also possible to improve the processability and productivity of TFTs by using a total of six mask processes. Furthermore, it is possible to form a pixel electrode pattern during the formation of source and drain electrodes, and to improve the uniformity of the alignment of the source and drain electrodes and the pixel electrode pattern. Also, because the thickness of a whole gate insulating layer is increased by as much as the thickness of a first gate insulating layer, the gate capacitance of the TFT substrate may be lowered, and thus, the power consumption of the TFT substrate may be reduced. Also, it is possible to prevent deterioration of the electric properties of the TFT substrate by removing part of the first gate insulating layer that overlaps a gate wire.

In the present invention, it is also possible to easily reduce the thickness of intermediate layers interposed between a common electrode and a pixel electrode by using a dry etching process after the formation of a semiconductor layer. Also, it is possible to minimize the occurrence of a ripple phenomenon in the common electrode by increasing the thickness of intermediate layers interposed between the common electrode and a data wire.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

1. A thin-film transistor (TFT) substrate comprising a first region, the first region comprising:
a gate wire;
a first gate insulating layer covering the gate wire;
a through-hole formed through the first gate insulating layer and positioned over a part of the gate wire;
a common electrode disposed on the first gate insulating layer and comprising first and second portions thereof which are isolated from each other, with the through-hole interposed therebetween;
a second gate insulating layer covering the common electrode, the first gate insulating layer, and the part of the gate wire over which the through-hole is positioned;
a semiconductor layer disposed on the second gate insulating layer;
a first etch barrier layer covering the semiconductor layer;
a first contact hole and a second contact hole, both of which are formed through the first etch barrier layer;
a source electrode disposed on the first etch barrier layer and electrically connected to the semiconductor layer via the first contact hole and comprising a transparent conductive oxide layer and a metal layer;
a drain electrode disposed on the first etch barrier layer and isolated from the source electrode, the drain electrode being electrically connected to the semiconductor layer via the second contact hole and comprising a transparent conductive oxide layer and a metal layer; and
a pixel electrode comprising the transparent conductive oxide layer, a first area of the pixel electrode being disposed on the first etch barrier layer and in the same layer as the transparent conductive oxide layer of the source electrode and the transparent conductive layer of the drain electrode.

2. (canceled)

3. The TFT substrate of claim 1, wherein the first region further comprises:
a passivation layer covering the source electrode and the drain electrode; and
a through-hole formed through the passivation layer; and
a second area of the pixel electrode is disposed in the through-hole.

4. The TFT substrate of claim 1, wherein the first area of the pixel electrode comprises at least one incision pattern.

5. The TFT substrate of claim 1, further comprising a second region comprising:
a gate wire;
a first gate insulating layer covering the gate wire;
a common electrode comprising first and second portions thereof which are disposed on the first gate insulating layer and isolated from each other;
a second gate insulating layer disposed on the first gate insulating layer and covering the common electrode;
a second etch barrier layer disposed on the second gate insulating layer;
a third contact hole formed through the first gate insulating layer, the second gate insulating layer, and the second etch barrier layer;
a data wire electrically connected to the gate wire via the third contact hole and insulated from the common electrode by the second gate insulating layer, and
a passivation layer covering the data wire.

6. The TFT substrate of claim 1, further comprising a third region, the third region comprising:
a gate wire;
a first gate insulating layer covering the gate wire;
a common electrode disposed on the first gate insulating layer and comprising first and second portions thereof which are isolated from each other;
a second gate insulating layer disposed on the first gate insulating layer and covering the common electrode;
a third etch barrier layer disposed on the second gate insulating layer;
a fourth contact hole formed through the first gate insulating layer, the second gate insulating layer, and the etch barrier layer;
a data wire electrically connected to the gate wire and the common electrode via the fourth contact hole; and
a passivation layer covering the data wire.

7. The TFT substrate of claim 5, wherein:
the data wire comprises a transparent conductive oxide layer and a metal layer disposed on the transparent conductive oxide layer; and
the transparent conductive oxide layer of the data wire contacts the gate wire via the third contact hole and is insulated from the common electrode by the second gate insulating layer.

8. The TFT substrate of claim 6, wherein:
the data wire comprises a transparent conductive oxide layer and a metal layer disposed on the transparent conductive oxide layer; and
the transparent conductive oxide layer of the data wire contacts the gate wire and the common electrode via the fourth contact hole.

9. The TFT substrate of claim 1, wherein the first contact hole and the second contact hole are formed in an area overlapping the semiconductor layer.

10. The TFT substrate of claim 1, wherein:
the first etch barrier layer comprises a first height portion and a second height portion having a height less than that of the first height portion; and
the second height portion is disposed in an area overlapping the semiconductor layer and is closer to at least one of the first contact hole and the second contact hole than the first height portion.

11. The TFT substrate of claim 1, wherein:
the first gate insulating layer comprises a first height portion and a second height portion having a height less than the first height portion;
the second height portion is disposed closer to the through-hole than is the third first height portion;
the second gate insulating layer comprises a third height portion and a fourth height portion having a height greater than that of the third height portion;
the third height portion is disposed in an area overlapping the common electrode; and
the fourth height portion is disposed closer to the through-hole than is the third height portion.

12. The TFT substrate of claim 5, wherein:
the first gate insulating layer comprises a first height portion and a second height portion having a height less than that of the first height portion;
the second height portion is disposed closer to the third contact hole than is the first height portion;
the second gate insulating layer comprises a third height portion and a fourth height portion having a height greater than that of the third height portion;
the third height portion is disposed in an area overlapping the common electrode; and
the fourth height portion is disposed closer to the third contact hole than is the third height portion.

13. The TFT substrate of claim 6, wherein:
the first gate insulating layer comprises a first height portion and a second height portion having a height less than that of the first height portion;
the second height portion is disposed closer to the fourth contact hole than is the first height portion; and
the second gate insulating layer comprises a third height portion.

14. A TFT substrate comprising:
a gate wire;
a first gate insulating layer covering the gate wire;
a through-hole formed through the first gate insulating layer and positioned over a part of the gate wire;
a common electrode disposed on the first gate insulating layer and comprising first and second portions thereof which are isolated from each other, with the through-hole interposed therebetween:
a second gate insulating layer covering the common electrode, the first gate insulating layer, and the part of the gate wire over which the through-hole is positioned;
a semiconductor layer disposed on the second gate insulating layer;
an etch barrier layer covering the semiconductor layer;
a contact hole formed through the etch barrier layer;
a data wire disposed directly on the etch barrier layer; and
a first region comprising the etch barrier layer comprising a first height portion and a second height portion having a second height less than a first height of the first height portion, the second height portion being disposed in an area overlapping the semiconductor layer to be closer to the contact hole than the first height portion; and
a second region comprising the etch barrier layer having a third height portion greater than the second height portion, wherein:
in the first region, the data wire is electrically connected to the semiconductor layer via the contact hole; and
in the second region, the data wire is insulated from a common electrode and is electrically connected to a gate wire via the contact hole.

15. The TFT substrate of claim 14, further comprising a third region comprising the etch barrier layer comprising a fourth height portion having a height greater than that of the second height portion.

16. (canceled)

17. The TFT substrate of claim 14, further comprising a third region in which the data wire is electrically connected to the gate wire and the common electrode via the contact hole.

18. (canceled)
